(19) United States
(12) Patent Application Publication
(10) Pub. No.: US 2009/0269681 A1
(43) Pub. Date: Oct. 29, 2009

(54) Method of detecting exposure boundary position, and method of fabricating semiconductor device

(75) Inventor: Ryoichi Aoyama, Tokyo (JP)

Correspondence Address: RABIN & Berdo, PC, 1101 14TH STREET, NW, SUITE 500, WASHINGTON, DC, 20005, US

(73) Assignee: OKI SEMICONDUCTOR CO., LTD., Tokyo (JP)

(21) Appl. No.: 12/382,254

(22) Filed: Mar. 12, 2009

(30) Foreign Application Priority Data
Apr. 28, 2008 (JP) 2008-117577

(51) Int. Cl. G03F 1/00; G03F 7/20

(52) U.S. Cl. 430/5; 430/319

(57) ABSTRACT

A region at which a light attenuation amount, converted into an exposure amount, is less than or equal to 100 msec is defined as an exposure region, and a region exceeding 100 msec is defined as a light shielded region. A dimension change amount of 0.12 μm is a threshold value of boundary position detection. A region where a dimension change amount of a projected image is less than or equal to 0.12 μm is an exposure region, and a region where a dimension change amount of a projected image exceeds 0.12 μm is a light shielded region. A position of an effective boundary line between the exposure region and the light shielded region can be determined. The position of the effective boundary line can be made to correspond to a position of a boundary line between an exposure region and a light shielded region on a photomask.

### CROSS-REFERENCE TO RELATED APPLICATION

This application claims priority under 35 USC 119 from Japanese Patent Application No. 2008-117577, the disclosure of which is incorporated by reference herein.

### BACKGROUND OF THE INVENTION

1. Field of the Invention

The present invention relates to a method of detecting an exposure boundary position in a semiconductor exposing device, and to a method of fabricating a semiconductor device that uses the detecting method.

2. Description of the Related Art

In fabricating a semiconductor device, a “photolithography technique” is generally used in which a mask pattern that is delineated on a photomask is transferred onto a photoresist (a photosensitive resin) formed on a wafer, and a resist pattern for forming elements and lines is formed. The photolithographic process in the fabrication of a semiconductor device uses a “semiconductor exposing device” such as a stepper or the like that illuminates ultraviolet rays or the like onto the photomask from a light source.

In the semiconductor exposing device, the mask pattern is transferred onto the photoresist by using the photomask as the original, and reducing and projecting the mask pattern onto the photoresist at a predetermined magnification by a projecting lens. By developing the photoresist after exposure, a resist pattern that corresponds to the mask pattern is formed on the wafer. The photomask that is used as the original plate is commonly called a “reticle”.

In the above-described semiconductor exposing device, as shown in FIG. 10, a reticle blind 24 is disposed, between a light source (not shown) and a photomask 28, as a light-shielding plate that shields a portion of the illumination light. The reticle blind 24 is usually structured from two, L-shaped light shielding plates 24A, 24B. The two light shielding plates 24A, 24B overlap one another such that a rectangular opening S is formed (refer to Japanese Patent Application Laid-Open (JP-A) No. 09-223653).

A portion of the illumination light from the light source is shielded by the reticle blind 24, and the remainder passes through the opening S of the reticle blind 24 and is irradiated onto the photomask 28. Namely, an exposure region 28E, at which light is not shielded by the reticle blind 24, and a light shielded region 28B, at which light is shielded by the reticle blind 24, exist on the photomask 28. The pattern that exists at the exposure region 28E is reduced and projected onto a photoresist 34 that is formed on a wafer 32, such that a specific region 34A is exposed.

By moving the respective light shielding plates 24A, 24B parallel within a plane that is orthogonal to the optical axis, the reticle blind 24 functions as a diaphragm mechanism that adjusts the surface area of the rectangular opening S (refer to JP-A No. 09-223653). Due to this function, a resist pattern can be formed on the wafer 32 by selecting an arbitrary pattern region formed at the photomask 28.

However, due to the diffraction phenomenon at the reticle blind, the light contrast gradually changes in a vicinity of the outline of the projected image formed on the photoresist. Therefore, the edge portion of the resist pattern that is formed on the wafer (the resist edge) does not become a completely straight line, and is a blurry shape. In order to avoid this problem, in cases in which it is desired to establish a clear distinction between the patterned region and the non-patterned region on the wafer, a light shielding zone formed of chromium (Cr) or the like is provided at the peripheral portion of the photomask.

The width of the light shielding zone generally must be around 1.5 mm, from the standpoint of positional accuracy of the reticle blind. Conventionally, adjustment of the surface area of the opening of the reticle blind is carried out mechanically by a driving mechanism, and the positional accuracy of the reticle blind is determined in accordance with the mechanical accuracy of the driving mechanism. Therefore, the width of the light shielding zone must have a relatively large amount of leeway that is in units of millimeters, and a wide light shielding zone of 1.5 mm is needed.

However, providing a light shielding zone at the photomask reduces the effective surface area of the photomask. If the effect surface area of the photomask is reduced, ultimately, the region that forms the mask pattern must also be made to be small, and there is also the adverse effect that the number of fabricated products (semiconductor devices) per wafer decreases.

In order to avoid such problems, it is important to accurately measure and manage the light blocking position of the reticle blind. Namely, it is important to establish a distinction between the exposure region, at which light is not shielded by the reticle blind, and the light shielded region, at which light is shielded by the reticle blind, on the photomask. For example, if the outline of the exposure region on the photomask is clear, it suffices to not provide a light shielding zone at the photomask, or at least, the width of the light shielding zone can be made to be narrow at about 1 mm to 0.5 mm. Due thereto, the problems of the effective surface area of the photomask being reduced and the number of fabricated products per wafer being reduced can be avoided.

Conventionally, as shown in FIG. 11, a ruler-like scale pattern is formed on the photomask, the photomask on which the scale pattern is formed is mounted to the exposure device, and the position of the reticle blind (the light shielding position) is measured. Specifically, the scale pattern is projected (transferred) onto the photoresist such that the edge of the reticle blind falls on the scale pattern of the photomask. The position of the reticle blind is measured by visually reading the position of the boundary line between the exposure region and the light shielded region from the transferred scale pattern by using an optical microscope.

For example, in the example shown in FIG. 11, the scale pattern is designed such that, in a case in which the light that passes through the opening of the reticle blind advances straight, the boundary line that shows the outline of the exposure region on the photomask is superposed on the “0” of the scale pattern that is formed on the photomask. However, in actuality, due to the diffraction phenomenon at the reticle blind, the exposure region on the photomask spreads toward the outer side (toward the right side in the drawing), and it can be understood that the boundary line is at the position of about “100” on the scale pattern.

However, because the light contrast gradually changes in a vicinity of the boundary line between the exposure region and the non-exposure region due to the aforementioned diffraction phenomenon caused by the reticle blind, the scale pattern that is transferred is also blurry, and it is difficult to read-out the exact position of the boundary line. Also in the example shown in FIG. 11, the scale pattern that exists at the outer side of the boundary line (in the light shielded region) is not transferred onto the photoresist. The position of the boundary line is read-out from only the transferred scale pattern.

Further, in the conventional measuring method, measurement requires time in order to visually read-out by using an optical microscope. In addition, because the judgment of the person who is doing the measuring is involved in determining whether it is or is not the boundary, errors arise among respective persons who carry out measurement, and it is difficult to measure the exact position of the boundary line.

### SUMMARY OF THE INVENTION

The present invention was developed in order to solve the above-described problems, and an object thereof is to provide a method of detecting an exposure boundary position that can easily and objectively detect a boundary line that shows the outline of a region where exposure light, that is not shielded by a reticle blind, reaches a photomask (i.e., an effective exposure region) in a semiconductor exposing device.

Another object of the present invention is to provide a method of fabricating a semiconductor device that can fabricate a semiconductor device efficiently by forming a circuit pattern of a semiconductor device within an exposure region of a photomask that exists at the inner side of a boundary line detected by using the method of detecting an exposure boundary position of the present invention.

In order to achieve the above object, the first aspect of the present invention provides a method of detecting an exposure boundary position that detects a position of a boundary line between a light shielded region and an exposure region on a photomask due to a reticle blind in a semiconductor exposing device that has the reticle blind adjusting an opening surface area through which a light beam from a light source passes, and a holding member holding the photomask, and that irradiates a light beam, that passes through an opening of the reticle blind, onto the photomask that is held at the holding member, and projects and exposes a pattern formed on the photomask onto a photoresist on a wafer, the method including:

a) preparing a photomask for measurement at which is formed a pattern for measurement that includes a plurality of pattern rows in each of which a plurality of unit measurement patterns, at which a dimension of a projected image projected onto a photoresist changes linearly in accordance with a decrease in an exposure amount, are arrayed in a predetermined direction;

b) holding the photomask for measurement by the holding member;

c) adjusting the opening surface area of the reticle blind;

d) illuminating the light beam, that passes through the opening of the reticle blind, onto the photomask for measurement that is held by the holding member, and printing, on a photoresist, the measurement pattern that is formed at the photomask for measurement;

e) selecting, from the measurement pattern printed on the photoresist, at least one measurement region at which a plurality of projected images of unit measurement patterns are arrayed in a given direction so as to exist at both sides of the boundary line;

f) successively measuring, at the selected measurement region and from a measurement start position that is at an exposure region side toward a light shielded region side, dimensions of the projected images of the unit measurement patterns that are arrayed in the given direction; and

g) on the basis of a position at which an amount of change of the dimension of the projected image exceeds a predetermined threshold value, detecting a position of a boundary line between a light shielded region and an exposure region on the photomask in the given direction.

In the second aspect of the present invention, the unit measurement pattern in the first aspect is structured so as to include at least a rectilinear grating pattern in which straight line portions of predetermined widths are arrayed in parallel at predetermined intervals in a direction orthogonal to the given direction.

In the third aspect of the present invention, the selected measurement region in the first aspect includes three or more unit measurement patterns at which dimensions of projected images can be measured.

In the fourth aspect of the present invention, at the photomask for measurement in the first aspect, a plurality of pattern rows, at each of which a plurality of the unit measurement patterns are arrayed at predetermined intervals in the given direction, are lined-up at predetermined intervals in a direction orthogonal to the given direction, and a plurality of the unit measurement patterns are arrayed in a matrix form over an entire mask surface.

In the fifth aspect of the present invention, the dimension of the projected image of the unit measurement pattern in the first aspect is measured by an optical-type dimension measuring device.

Further, the sixth aspect of the present invention provides a method of fabricating a semiconductor device that fabricates a semiconductor device, the method including:

detecting a position of a boundary line between a light shielded region and an exposure region on a photomask in a semiconductor exposing device by using the method of detecting an exposure boundary position of claim 1;

forming a circuit pattern of a semiconductor device within an exposure region of the photomask that exists at an inner side of a detected boundary line;

holding, by the holding member, the photomask on which the circuit pattern is formed; and

illuminating a light beam, that passes through the opening of the reticle blind, onto the photomask held by the holding member, and printing the circuit pattern, that is formed on the photomask, onto a photoresist on a wafer.

In accordance with the first aspect of the present invention, there is the effect that a boundary line that shows the outline of a region at which exposure light, that was not shielded by a reticle blind, reaches a photomask (i.e., the effective exposure region) in a semiconductor exposing device, can be detected easily and objectively.

In accordance with the second aspect of the present invention, there is the effect that a unit measurement pattern, at which the dimension of a projected image projected on a photoresist changes linearly in accordance with a decrease in the exposure amount, can be structured simply.

In accordance with the third aspect of the present invention, there is the effect that a position, at which the amount of change in the dimension of the projected image exceeds a predetermined threshold value, can be specified clearly by three-point measurement.

In accordance with the fourth aspect of the present invention, there is the effect that a measurement region can be selected arbitrarily from a measurement pattern that is printed on a photoresist.

In accordance with the fifth aspect of the present invention, there is the effect that the position of a boundary line can be detected by an easy method, as compared with a conventional measurement method in which measurement is carried out visually by using an optical microscope.

In accordance with the sixth aspect of the present invention, there is the effect that a semiconductor device can be fabricated efficiently by forming the circuit pattern of the semiconductor device within an exposure region of a photomask that exists at the inner side of a boundary line that is detected by using the method of detecting an exposure boundary position of the present invention.

### BRIEF DESCRIPTION OF THE DRAWINGS

Preferred exemplary embodiments of the present invention will be described in detail based on the following figures, wherein:

FIG. 1 is a schematic drawing showing the structure of a semiconductor exposing device equipped with a reticle blind;

FIG. 2A is a schematic drawing showing the structure of the reticle blind;

FIG. 2B is a schematic drawing showing the structure of the reticle blind;

FIG. 3A is a drawing showing an example of a structure of a unit measurement pattern;

FIG. 3B is a plan view showing an example of a photomask for measurement at which the unit measurement patterns are arrayed;

FIG. 3C is a plan view showing a state in which the photomask for measurement is partially shielded from light;

FIG. 4A is a graph showing dimension change amount with respect to exposure amount;

FIG. 4B is a drawing showing dimensions of a projected image at an exposure region;

FIG. 4C is a drawing showing dimensions of a projected image within a region at which the exposure amount is reduced;

FIG. 5 is a plan view showing the entirety of a projected image that is printed on a photoresist by using the photomask for measurement;

FIG. 6 is a drawing showing a state in which dimensions of projected images, that are arrayed at a selected measurement region, are successively measured;

FIG. 7 is a graph showing fluctuations in dimensions of projected images with respect to distance from a measurement start position;

FIG. 8A is a drawing showing another structural example of a unit measurement pattern;

FIG. 8B is a drawing showing yet another structural example of a unit measurement pattern;

FIG. 9 is a plan view showing another structural example of a photomask for measurement;

FIG. 10 is a schematic drawing for explaining a state in which illumination light is irradiated onto a photomask via a reticle blind;

FIG. 11 is a drawing for explaining a conventional method of measuring the position of the reticle blind;

FIG. 12A is a drawing for explaining the diffraction phenomenon due to the reticle blind; and

FIG. 12B is a drawing for explaining the diffraction phenomenon due to the reticle blind.

### DETAILED DESCRIPTION OF THE INVENTION

Examples of exemplary embodiments of the present invention will be described in detail hereinafter with reference to the drawings.

### <Structure of Semiconductor Exposing Device>

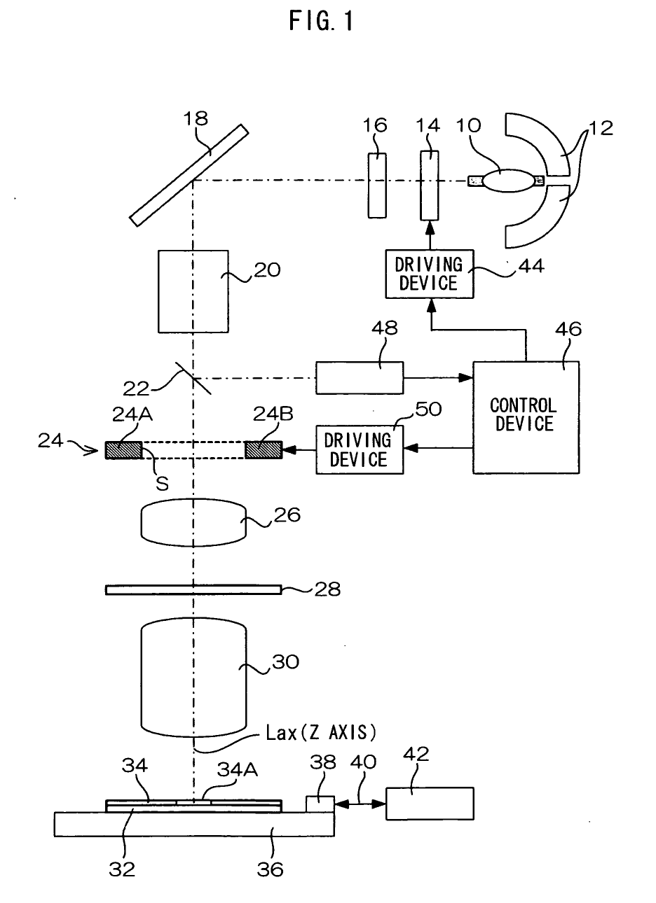

FIG. 1 is a schematic drawing showing the structure of a semiconductor exposing device equipped with a reticle blind.

The semiconductor exposing device has a high-luminance light source 10 such as a high-pressure mercury lamp, an ultra-high-pressure mercury lamp or the like. An elliptical mirror 12, that collects illumination light exiting from the light source 10, is disposed behind the light source 10. A shutter 14 that is structured so as to be able to open and close, a wavelength selecting filter 16 through which only the wavelength needed for exposure passes, and a reflecting mirror 18 are disposed in front of the light source 10, in that order along the optical path from the light source 10 side.

A fly-eye integrator 20, that adjusts incident light into a light beam of a uniform illuminance distribution, and a half-mirror 22, that transmits a portion of incident light through and reflects the remaining portion, are disposed at the light reflecting side of the reflecting mirror 18, in that order along the optical path from the reflecting mirror 18 side. Further, a reticle blind 24 serving as a diaphragm means and a lens system 26 are disposed at the light transmitting side of the half-mirror 22, in that order along the optical path from the half-mirror 22 side. On the other hand, an integral exposure amount meter 48 that measures the integral exposure amount, is disposed at the light reflecting side of the half-mirror 22.

The shutter 14 is connected to a control device 46 via a driving device 44. Further, the integral exposure amount meter 48 as well is connected to the control device 46. On the basis of the output of the integral exposure amount meter 48, the control device 46 generates a control signal that controls the opening/closing time of the shutter 14 (i.e., the exposure amount). On the basis of the control signal, the driving device 44 opens and closes the shutter 14 so as to control the exposure amount.

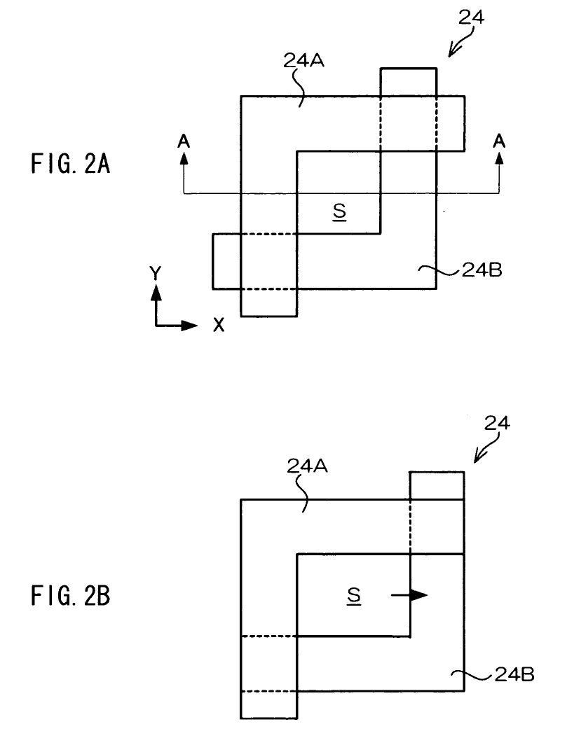

FIG. 2A and FIG. 2B are schematic drawings showing the structure of the reticle blind. As shown in FIG. 2A, the reticle blind 24 is structured by two metal L-shaped light shielding plates 24A, 24B being overlapped. The two light shielding plates 24A, 24B are disposed parallel to a plane that is orthogonal to an optical axis Lax of the illumination light, and are driven independently by a driving device 50, and move in parallel within the plane that is orthogonal to the optical axis Lax. The reticle blind 24 thereby functions as a diaphragm mechanism that adjusts the surface area of a rectangular opening S. For example, as shown in FIG. 2B, the surface area of the rectangular opening S can be increased by moving only the light shielding plate 24B in the x direction. The driving device 50 is connected to the control device 46, and drives the respective light shielding plates 24A, 24B independently on the basis of control signals.

A holding stage (not shown) that holds a photomask 28 is disposed at the light exiting side of the lens system 26. The photomask 28 is held at the holding stage, and is disposed so as to be fixed at the imaging position of the lens system 26. A projecting optical system 30, that projects the pattern formed on the photomask 28 while reducing it to 1/10, ⅕ or the like, is disposed at the light exiting side of the photomask 28. A stage 36, on which is disposed a wafer 32 on which a photoresist 34 is coated, is disposed at the light exiting side of the projecting optical system 30. The wafer 32 is disposed so as to be fixed on the stage 36.

The stage 36 is a known structure in which a pair of blocks, that are movable in directions orthogonal to one another, are overlapped. The stage 36 is structured so as to be movable in xy directions that are orthogonal to a z axis, where the direction of the optical axis (Lax) is the z axis. The position of the wafer 32 within a horizontal plate is adjusted by moving the stage 36 in the xy directions. Note that the position of the stage 36 is detected by a laser interferometer 42 that irradiates laser light 40 toward a moving mirror 38 on the stage 36 and measures the distance on the basis of the interference between the reflected light thereof and incident light.

### <Operation of Semiconductor Exposing Device>

Operation of the semiconductor exposing device shown in FIG. 1 will be briefly described next. The illumination light that exits from the light source 10 is collected at the elliptical mirror 12, and is incident on the wavelength selecting filter 16 in response to the opening/closing operation of the shutter 14. The wavelength selecting filter 16 passes only the wavelength that is needed for exposure. For example, the wavelength selecting filter 16 selectively passes i-rays (wavelength 365 nm) of a high-pressure mercury lamp. The illumination light that passes through the wavelength selecting filter 16 is reflected at the reflecting mirror 18, is adjusted into a light beam of a uniform illuminance distribution by the fly-eye integrator 20, and is incident on the half-mirror 22.

The illumination light that is transmitted through the half-mirror 22 reaches the reticle blind 24. The reticle blind 24 adjusts the range of exposure on the photomask 28 by the illumination light, by the size of the opening S of the reticle blind 24 being changed. Further, a portion of the light beam exiting from the fly-eye integrator 20 is reflected at the half-mirror 22 and is incident on the integral exposure amount meter 48, and control of the exposure amount is carried out.

The illumination light that passes through the opening S of the reticle blind 24 is imaged on the photomask 28 by the lens system 26, and the desired range of the photomask 28 is illuminated. The pattern image existing in the illumination range of the photomask 28 is projected while being reduced to 1/10, ⅕ or the like by the projecting optical system 30, and is imaged on the photoresist 34 that is coated on the wafer 32. The pattern image of the photomask 28 is thereby exposed on the specific region 34A of the photoresist 34.

In a case in which the exposure region on the photoresist 34 is exposed while divided into “unit regions”, exposure of one time is finished for the one photomask 28 (pattern region), and thereafter, the photomask 28 is replaced. Then, the stage 36 is driven, and another exposure region on the photoresist 34 is positioned with respect to the projecting optical system 30 and is exposed. Thereafter, similar procedures are repeated each time exposure is finished, such that the entire region of the photoresist 34 that is coated on the wafer 32 is exposed.

Further, by forming plural types of patterns on the one photomask 28 and adjusting the surface area of the opening of the reticle blind 24, the range of exposure on the photomask 28 that is exposed by the illumination light is changed, an arbitrary pattern region is selected from the photomask 28, and a resist pattern can be formed on the wafer 32.

### <Method of Detecting Exposure Boundary Position>

Next, the “method of detecting an exposure boundary position” in the semiconductor exposing device will be described. In this detecting method, the position of the boundary line that shows the outline of the region that the illumination light, that is not shielded at the reticle blind 24, reaches on the photomask 28 (i.e., the effective exposure region), is detected as the position of the boundary line between the light shielded region and the exposure region (i.e., the “exposure boundary position”), while taking the diffraction phenomenon at the reticle blind 24 into consideration. Further, this detecting method utilizes a “photomask for measurement” that will be described hereinafter, in order to easily and objectively detect the exposure boundary position on the basis of a specific index. Hereinafter, the photomask for measurement will be denoted by reference numeral “28M” in order to distinguish it from the ordinary photomask 28 that is used for circuit pattern formation.

### (Photomask for Measurement)

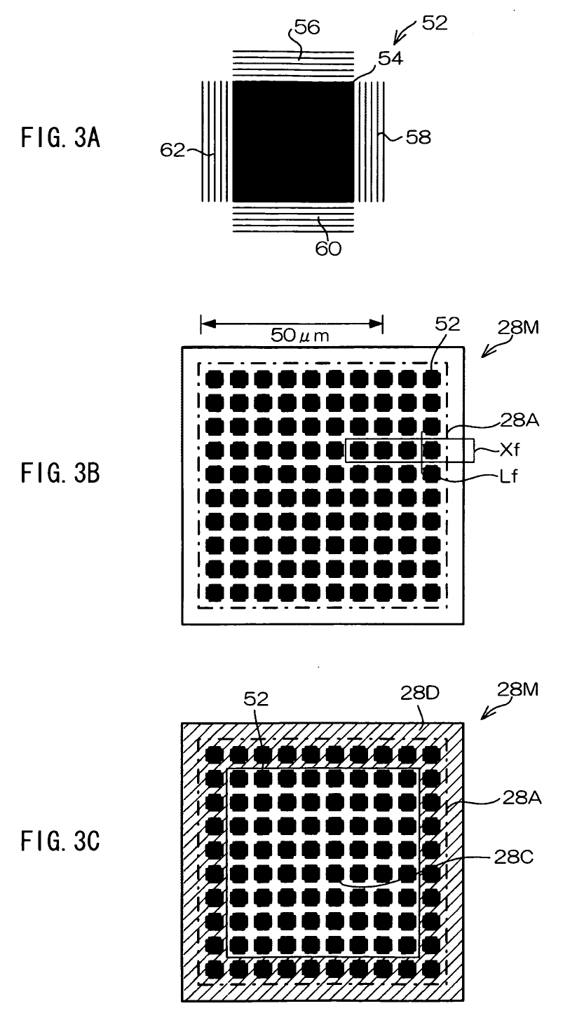

FIG. 3A is a drawing showing an example of the structure of a “unit measurement pattern” that is formed at the photomask for measurement 28M. FIG. 3B is a plan view showing an example of the photomask for measurement 28M at which the “unit measurement patterns” are arrayed. FIG. 3C is a plan view showing a state in which the photomask for measurement 28M is partially shielded from light.

As shown in FIG. 3A, a unit measurement pattern 52 has a rectangular pattern 54 that is blackened-in. Here, the respective edges that structure the outer periphery of the rectangular pattern 54 are differentiated as the top edge, the right edge, the bottom edge, and the left edge. At the upper side of the rectangular pattern 54, plural line segments, which are predetermined widths and are the same length as the top edge, are arrayed at predetermined intervals in parallel to the top edge of the rectangular pattern 54. The pattern that is formed from the plural line segments that are arrayed at predetermined intervals (the set of the lines and spaces) is called a rectilinear grating pattern. In this example, five line segments are arrayed in the rectilinear grating pattern. Namely, a rectilinear grating pattern 56 is disposed at the upper side of the rectangular pattern 54.

Further, plural (five in the present example) line segments, that are predetermined widths and are the same length as the right edge, are arrayed at predetermined intervals in parallel to the right edge of the rectangular pattern 54, at the right side of the rectangular pattern 54. Namely, a rectilinear grating pattern 58 is disposed at the right side of the rectangular pattern 54. Similarly, a rectilinear grating pattern 60 is disposed at the lower side of the rectangular pattern 54, and a rectilinear grating pattern 62 is disposed at the left side of the rectangular pattern 54.

As described above, the unit measurement pattern 52 is structured such that the blackened-in rectangular pattern 54 is disposed at the central portion, and the rectilinear grating patterns 56, 58, 60, 62 are disposed at the outer peripheral portion. The overall dimension of the unit measurement pattern 52 is the length or the width of the unit measurement pattern 52 in the direction along one grating array direction. The dimension of the unit measurement pattern 52 is preferably around 50 μm in order to be measured accurately by a known, optical-type dimension measuring device.

In the example shown in FIG. 3A, the dimension of the unit measurement pattern 52 in the top-bottom direction is 50 μm, and the dimension thereof in the left-right direction is 50 μm. Given that the line width (the width of one line segment) is 0.52 μm and the space width (the distance between two adjacent line segments) is 0.52 μm, one edge of the rectangular pattern 54 is 39.6 μm.

As will be described later, the unit measurement pattern, that is shown as an example in FIG. 3A and includes the rectilinear grating patterns (the sets of lines and spaces), has the property that, as the exposure amount decreases, the dimension of the projected image that is projected onto the photoresist changes sensitively. In the present exemplary embodiment, the position of the boundary line showing the outline of the effective exposure region is detected as the “exposure boundary position” by utilizing this property of the unit measurement pattern.

As shown in FIG. 3B, the photomask for measurement 28M is a rectangular flat plate as seen in plan view, and is structured of a material that is transparent with respect to the illumination light. Numerous unit measurement patterns 52 are formed at the photomask for measurement 28M at the entire mask. For example, a pattern is formed by a light shielding material such as chromium (Cr) or the like on a quartz glass plate. An exposable region is set at the usual photomask 28 in order to expose (pattern) the unit region of the wafer. Similarly to the usual photomask 28, an exposable region 28A (the region surrounded by the one-dot chain line) is set at the photomask for measurement 28M as well. The unit measurement patterns 52 are formed within this exposable region 28A.

In this example, ten pattern rows, in each of which ten of the unit measurement patterns 52 are arrayed at predetermined intervals in the left-right direction, are lined-up at predetermined intervals in the top-bottom direction, such that 100 of the unit measurement patterns 52 are disposed in a 10×10 matrix form. The “arranged number” and “arrangement pitch” of the unit measurement patterns can be selected arbitrarily. From the standpoint of accuracy of measurement, it is preferable that the arrangement pitch be less than or equal to 200 μm. A narrower arrangement pitch results in improved measurement accuracy.

### (Diffraction Phenomenon due to Reticle Blind)

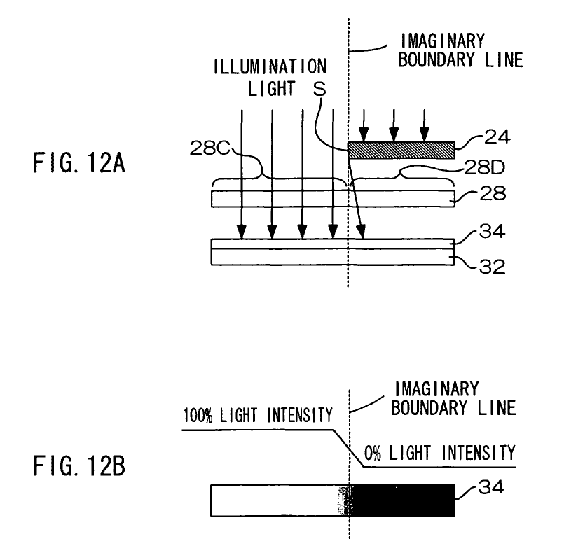

Here, the “diffraction phenomenon” due to the reticle blind will be explained with reference to FIG. 12A and FIG. 12B. In this explanation, the light that passes through the opening S of the reticle blind 24 is illuminated onto the photomask 28 at an equal magnification, and the light that is modulated at the mask pattern formed on the photomask 28 is projected at an equal magnification onto the photoresist 34 formed on the wafer 32.

Assuming that the illumination light from the light source passes through the opening S of the reticle blind 24 and advances straight, the portion on the photomask 28, which portion opposes the opening S of the reticle blind 24, is an exposure region 28C, and the portion on the photomask 28, which portion opposes the light shielding plates 24A, 24B of the reticle blind 24, is a light shielded region 28D. The imaginary boundary line between the exposure region 28C and the light shielded region 28D is shown by the dotted line.

However, in actuality, the illumination light is diffracted when passing through the opening S of the reticle blind 24, and therefore, as shown in FIG. 12B, a clear boundary line does not exist between the exposure region 28C and the light shielded region 28D. For example, assuming that, at the portion that is shielded from light by the reticle blind 24, the light that reaches the photoresist 34 is 0%, and, at the portion that is not shielded from light by the reticle blind 24, 100% of the light that passes through the opening S reaches the photoresist 34, the light intensity of the exposure light that exposes the photoresist 34 gradually varies from 100% to 0% before and behind the imaginary boundary line due to the diffraction phenomenon at the opening S of the reticle blind 24.

### (Principles of Detection of Boundary Position)

As shown in FIG. 3C, when the surface area of the opening S of the reticle blind 24 is made to be small, and a region that is one size narrower than the exposable region 28A is made to be the exposure region 28C, a portion of the region at which the unit measurement patterns 52 are formed also is shielded from light. The exposure amounts of the unit measurement patterns 52 that exist in the exposure region 28C, the unit measurement patterns 52 that exist at the light shielded region 28D, and the unit measurement patterns 52 that exist in a vicinity of the boundary between the exposure region 28C and the light shielded region 28D, respectively differ due to the “diffraction phenomenon” caused by the reticle blind.

As described above, the unit measurement pattern that is shown as an example in FIG. 3A has the property that, as the exposure amount decreases, the dimension of the projected image that is projected onto the photoresist changes sensitively. In the present exemplary embodiment, by utilizing this property of the unit measurement pattern, the position of the boundary line showing the outline of the region at which the illumination light, that is not shielded by the reticle blind 24, reaches the photomask 28 (i.e., the effective exposure region) is detected, from the dimensions of the projected images, as the position of the boundary line between the light shielded region and the exposure region (i.e., the exposure boundary position).

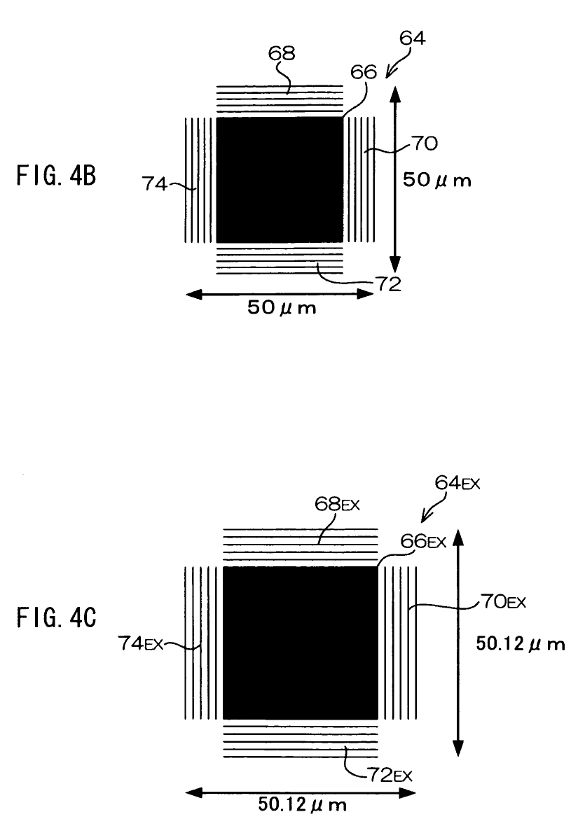

By using the semiconductor exposing device shown in FIG. 1, the measurement pattern of the photomask for measurement 28M was projected and exposed at an equal magnification onto the photoresist 34 coated on the wafer 32, while the exposure amount was changed. The measurement pattern was printed on the photoresist 34. Plural projected images 64 were printed on the photoresist 34 (see FIG. 5) so as to correspond respectively to the plural unit measurement patterns 52 included in the measurement pattern.

The dimensions of the projected images 64 printed on the photoresist 34 were measured by a known, optical-type dimension measuring device such as, for example, a “resist overlap measuring device”. For the exposure wavelength, i-rays (wavelength 365 nm) were used. A positive resist that was sensitive to i-rays and had a film thickness of 15100 Å was used as the photoresist 34. The pattern shown in FIG. 3A was used as the unit measurement pattern 52. The overall dimension of the unit measurement pattern 52 was 50 μm. Further, the line width of the rectilinear grating pattern was 0.52 μm, and the space width was 0.52 μm.

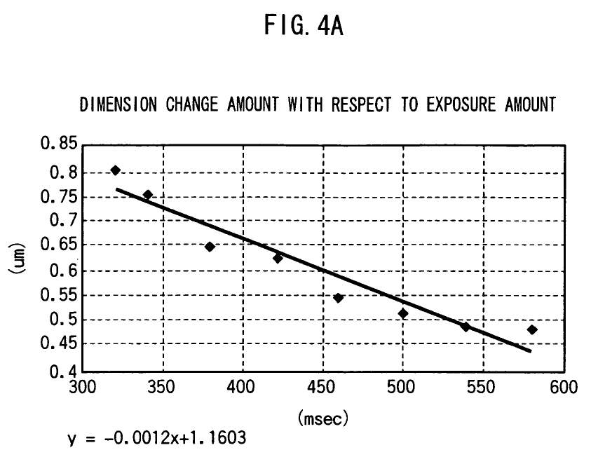

FIG. 4A is a graph that concretely shows the “dimension change amounts with respect to exposure amounts” that were obtained under the above-described conditions. The dimension of the projected image (unit: μm) is shown on the vertical axis. The time-converted exposure amount (unit: milliseconds [msec]) is shown on the horizontal axis. From this graph, it can be understood that, as the exposure amount decreases, the dimension of the projected image changes linearly. When the exposure amount decreases, the dimension of the projected image becomes longer. The dimension of the projected image changes around 0.12 μm with respect to a change in the exposure amount of 100 msec.

Namely, the unit measurement pattern 52, that exists in the exposure region 28C that is not shielded from light by the reticle blind 24, is projected and exposed on the photoresist 34 at the same size, and the projected image 64 whose dimension is 50 μm is obtained as shown in FIG. 4B. The projected image 64 is structured by a rectangular pattern 66, and rectilinear grating patterns 68, 70, 72, 74 that correspond to the respective portions of the unit measurement pattern 52.

On the other hand, in a vicinity of the boundary between the exposure region 28C and the light shielded region 28D, the light intensity of the exposure light that exposes the photoresist 34 gradually changes from 100% to 0% before and behind the imaginary boundary line, due to the diffraction phenomenon at the opening S of the reticle blind 24. When the unit measurement pattern 52 that exists in the region whose light attenuation amount due to the diffraction phenomenon is 100 msec when converted into an exposure amount, is projected and exposed onto the photoresist 34, as shown in FIG. 4C, a projected image 64_{EX} whose dimension is 50.12 μm is obtained. The projected image 64_{EX} is structured by a rectangular pattern 66_{EX} and rectilinear grating patterns 68_{EX}, 70_{EX}, 72_{EX}, 74_{EX} that correspond to the respective portions of the unit measurement pattern 52.

The dimension change amount of about 0.12 μm is a range that can be measured by a known, optical-type dimension measuring device. Namely, this is a range in which, if this amount of change is set as a threshold value, it can be judged, from the dimension that is measured at a known, optical-type dimension measuring device, whether or not the set threshold value is exceeded.

### (Procedures of Detecting Boundary Position)

FIG. 5 is a plan view showing an entire projected image of a measurement pattern that is printed on a photoresist. By using the semiconductor exposing device shown in FIG. 1, the light shielding plates 24A, 24B of the reticle blind 24 respectively are set at the position to be evaluated, and the photomask for measurement 28M is projected and exposed onto the photoresist 34 that is coated on the wafer 32. The specific region 34A of the photoresist 34 is exposed, and the projected image of a measurement pattern such as shown in FIG. 5 is printed thereon.

An exposure region 34C, that is exposed by the light that passes through the opening S of the reticle blind 24, and a light shielded region 34B, that is shielded from light by the reticle blind 24, are formed at the specific region 34A. At the exposure region 34C, the photomask for measurement 28M is illuminated by the light that passes through the opening S of the reticle blind 24, and the projected images 64 of the unit measurement patterns are printed on the photoresist 34.

The position of the boundary line between the exposure region 34C and the light shielded region 34B on the photoresist 34 corresponds to the position of the boundary line between the exposure region 28C and the light shielded region 28D on the photomask for measurement 28M. Accordingly, the position of the boundary line on the photomask for measurement 28M can be specified from the position of the boundary line determined on the photoresist 34. First, a position, on the photoresist 34, that is separated by about 500 μm to 1000 μm from the imaginary boundary line between the exposure region 34C and the light shielded region 34B (the set position of the reticle blind) in a case in which it is supposed that there is no diffraction phenomenon, is made to be the “measurement start position”. Next, a “measurement region”, at which the plural projected images 64 are lined-up in a row so as to start from this measurement start position and so as to exist at both sides of the boundary line, is selected. For example, in the projected image shown in FIG. 5, region X that is surrounded by the dotted line is selected as the “measurement region”.

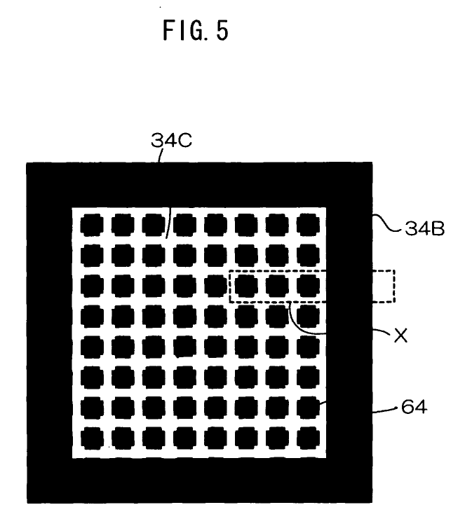

Next, the dimensions of the projected images 64 within the selected measurement region are successively measured. FIG. 6 is a drawing illustrating the state in which the dimensions of the “unit measurement patterns (projected images)” that are arrayed at the selected measurement region are successively measured. Within the selected measurement region, the plural projected images 64 are lined-up in a row so as to exist at both sides of the boundary line. The dimensions of these projected images 64 are successively measured from the measurement start position toward the light shielded region 34B. For example, in the example shown in FIG. 6, four projected images 64₁ through 64₄ are lined-up in a lateral row in that order from the measurement start position within the selected measurement region so as to exist at both sides of the boundary line. By using a known, optical-type dimension measuring device, the dimensions of the projected images 64 are measured in the order of the projected image 64₁, the projected image 64₂, the projected image 64₃, the projected image 64₄.

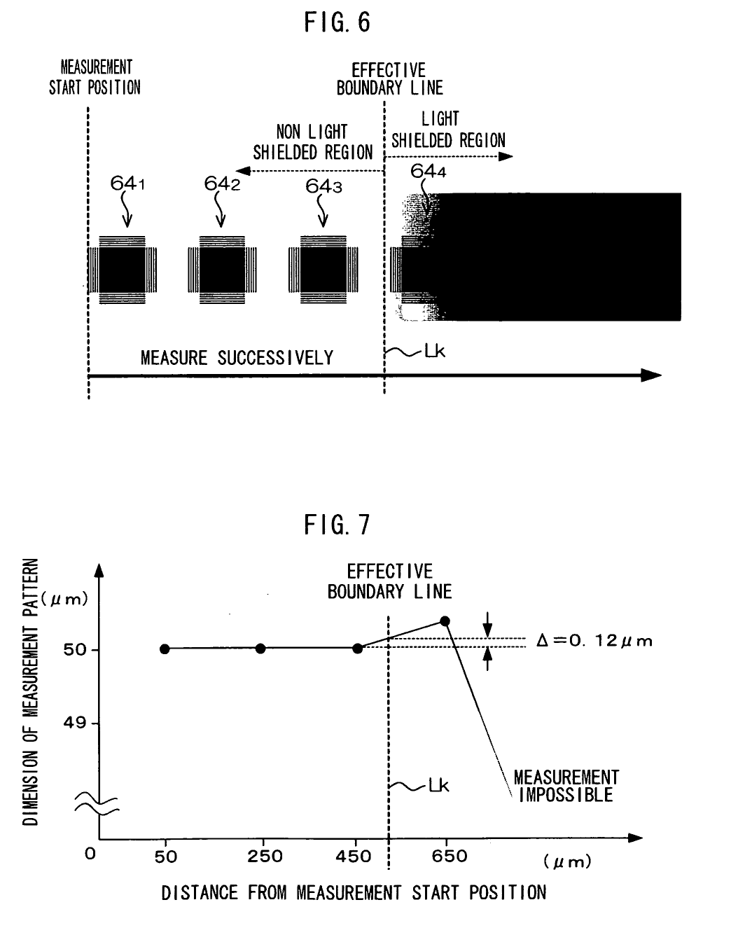

FIG. 7 is a graph showing changes in the dimensions of the “unit measurement patterns (projected images)” with respect to the distance from the measurement start position. The measured dimensions of the projected images 64 are plotted in accordance with the distance from the measurement start position. From the projected image 64₁ to the projected image 64₂, the dimension of the projected image is substantially constant at 50 μm. At the next projected image 64₃, due to the light attenuating effects caused by diffraction, the dimension of the projected image increases slightly from 50 μm. At the next projected image 64₄, the dimension of the projected image is 50.3 μm. Note that, even if a corresponding next unit measurement pattern 52 exists at the photomask for measurement 28M, this is a light shielded region, and therefore, a projected image is not formed, and the dimension of this next projected image cannot be measured.

Here, when the region whose light attenuation amount as converted into an exposure amount is less than or equal to 100 msec is defined as the exposure region 34C (non light shielded region), and the region exceeding 100 msec is defined as the light shielded region 34B, 0.12 μm is the threshold value for the dimension change amount. Namely, a region whose dimension change amount of the projected image 64 is less than or equal to 0.12 μm is the exposure region 34C, and a region whose dimension change amount of the projected image 64 exceeds 0.12 μm is the light shielded region 34B.

The position of an “effective boundary line Lₖ” between the exposure region 34C and the light shielded region 34B can be determined as shown by the dotted line from the point of intersection between a straight line, that passes through the point corresponding to the projected image 64₃ and the point corresponding to the projected image 64₄, and a straight line, that prescribes the upper limit of a dimension change amount Δ. In FIG. 7, if measurement is started from the left end of the projected image 64, and the respective projected images of dimensions of 50 μm are formed at a pitch of 200 μm at the exposure region, the boundary line Lₖ exists at a position that is around 500 μm from the measurement start position.

The position of the “effective boundary line Lₖ” on the photoresist 34 can be made to correspond to the position of the boundary line between the exposure region 28C and the light shielded region 28D on the photomask for measurement 28M. For example, measurement region X shown in FIG. 5 corresponds to region X_{f} of the photomask for measurement 28M shown in FIG. 3B. The boundary line Lₖ shown in FIG. 6 and FIG. 7 corresponds to boundary line L_{f} shown in FIG. 3B. In this way, the exposure boundary position (the position of the boundary line L_{f}) on the photomask for measurement 28, at the set position of the reticle blind 24, can be specified.

Note that the above describes an example in which the measurement pattern that is formed at the photomask for measurement 28M is printed at an equal magnification onto the photoresist 34. However, if the measurement pattern is projected while being reduced, the position of the boundary line L_{f} on the photomask for measurement 28 can be determined by magnification conversion from the position of the boundary line Lₖ on the photoresist 34.

In the projected image shown in FIG. 5, the shape of the exposure region 34C is rectangular, and there are four boundary lines. If all of the boundary lines are to be specified, a “measurement region” is selected for each of the four boundary lines. Further, even in the case of one boundary line, the measurement accuracy is improved by selecting plural “measurement regions”.

Further, by inputting and analyzing the measured exposure boundary position at a computer (e.g., the control device 46 of FIG. 1) for each of the set positions of the light shielding plates 24A, 24B of the reticle blind 24, the effective exposure region and light shielded region on the photomask 28 can be accurately grasped in accordance with the set positions of the light shielding plates 24A, 24B.

Further, the set positions of the light shielding plates 24A, 24B can be adjusted such that a desired region of the photomask 28 is exposed. For example, measured exposure boundary positions are stored in a table of a storage section (not shown) of the control device 46 in association with set positions of the light shielding plates 24A, 24B, and control signals for exposing the photomask 28 are generated at the control device 46 on the basis of this table, and the control signals are inputted to the driving device 50 and the light shielding plates 24A, 24B are driven. The light shielding plates 24A, 24B can thereby be driven and controlled so as to expose a desired region of the photomask 28.

As described above, the present exemplary embodiment utilizes a unit measurement pattern that has the property that, as the exposure amount decreases, the dimension of the projected image that is projected onto the photoresist changes sensitively. The position of the boundary line between the light shielded region and the exposure region is detected on the basis of an index that is the dimension change amount of the projected image of the unit measurement pattern. Therefore, the position of the boundary line can be specified objectively.

Further, the dimension of the projected image changes linearly with respect to a change in the exposure amount. Therefore, measuring the dimension of the projected image is, indirectly, measuring the exposure amount. Accordingly, the position of the boundary line, that shows the outline of the region at which the illumination light not shielded at the reticle blind actually reaches the photomask due to the diffraction phenomenon (i.e., the effective exposure region), can be specified.

Moreover, because the dimension of the projected image formed on the photoresist can be measured by a known, optical-type dimension measuring device, the position of the boundary line can be detected rapidly and by an easy method, as compared with a conventional measuring method in which measurement is carried out visually by using an optical microscope.

### MODIFIED EXAMPLES OF PHOTOMASK FOR MEASUREMENT

### Modified Example 1

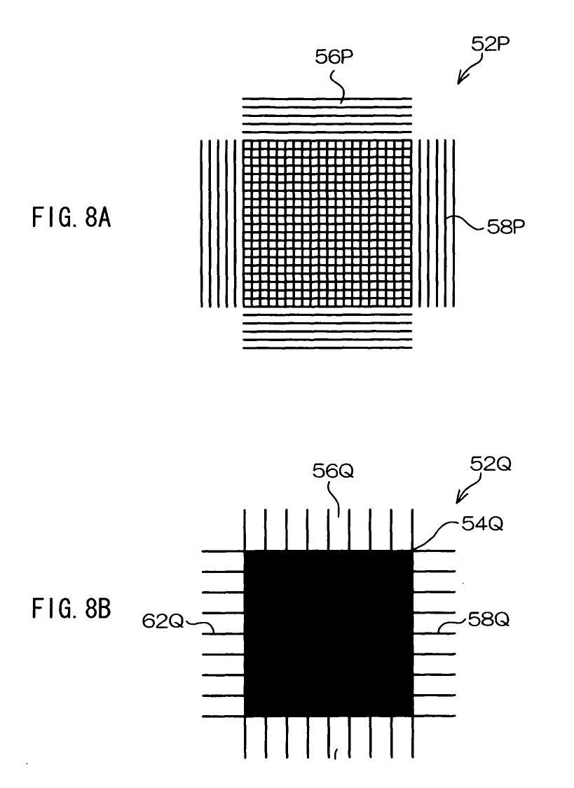

The above exemplary embodiment describes an example (see FIG. 3A) using a “unit measurement pattern” of a structure in which a rectangular pattern that is blackened-in is disposed at the central portion and rectilinear grating patterns (sets of lines and spaces) are disposed only at the outer peripheral portion. However, it suffices for the unit measurement pattern to be a structure that includes a rectilinear grating pattern, and the above-described exemplary embodiment is not intended to limit the structure of the unit measurement pattern to the structure shown in FIG. 3A. FIG. 8A and FIG. 8B are drawings showing other structural examples of the unit measurement pattern.

For example, as shown in FIG. 8A, a unit measurement pattern 52P is structured by a rectilinear grating pattern 56P, in which line segments of a predetermined length are arrayed at predetermined intervals in a predetermined direction (the top-bottom direction in the drawing), and a rectilinear grating pattern 58P, in which line segments of a predetermined length are arrayed at predetermined intervals in a direction (the left-right direction in the drawing) that is orthogonal to the predetermined direction. As a result of the rectilinear grating pattern 56P and the rectilinear grating pattern 58P intersecting, a grating-like pattern is formed at the central portion of the unit measurement pattern 52P.

Further, as shown in FIG. 8B for example, a unit measurement pattern 52Q is structured by a rectangular pattern 54Q, that is blackened-in and is disposed at the central portion, and rectilinear grating patterns 56Q, 58Q, 60Q, 62Q disposed at the outer peripheral portion. At the rectilinear grating pattern 56Q that is disposed at the upper side of the rectangular pattern 54Q, plural line segments of a predetermined length and a predetermined width are arrayed at predetermined intervals so as to be perpendicular to the top edge of the rectangular pattern 54Q. In this example, the rectilinear grating pattern 56Q is structured by nine line segments that are shorter than one edge of the rectangular pattern 54Q.

Moreover, at the rectilinear grating pattern 58Q that is disposed at the right side of the rectangular pattern 54Q, plural line segments of a predetermined length and a predetermined width are arrayed at predetermined intervals so as to be perpendicular to the right edge of the rectangular pattern 54Q. In this example, the rectilinear grating pattern 58Q is structured by nine line segments that are shorter than one edge of the rectangular pattern 54Q. Similarly, the rectilinear grating pattern 60Q is disposed at the lower side of the rectangular pattern 54Q, and the rectilinear grating pattern 62Q is disposed at the left side of the rectangular pattern 54Q.

Also with the unit measurement patterns 52P, 52Q that are shown in FIG. 8A and FIG. 8B, the dimension of the projected image changes linearly in accordance with a decrease in the exposure amount, and, in the same way as in the above-described exemplary embodiment, the dimensions of the projected images that are arrayed in the measurement region are successively measured, and a position at which the dimension change amount of the projected image exceeds a threshold value can be specified as the position of the boundary line between the exposure region and the light shielded region.

### Modified Example 2

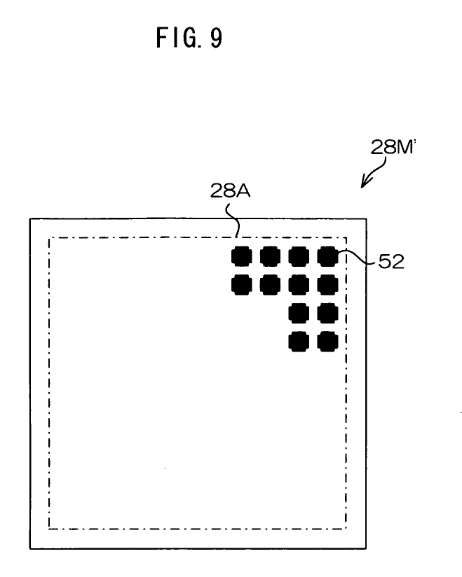

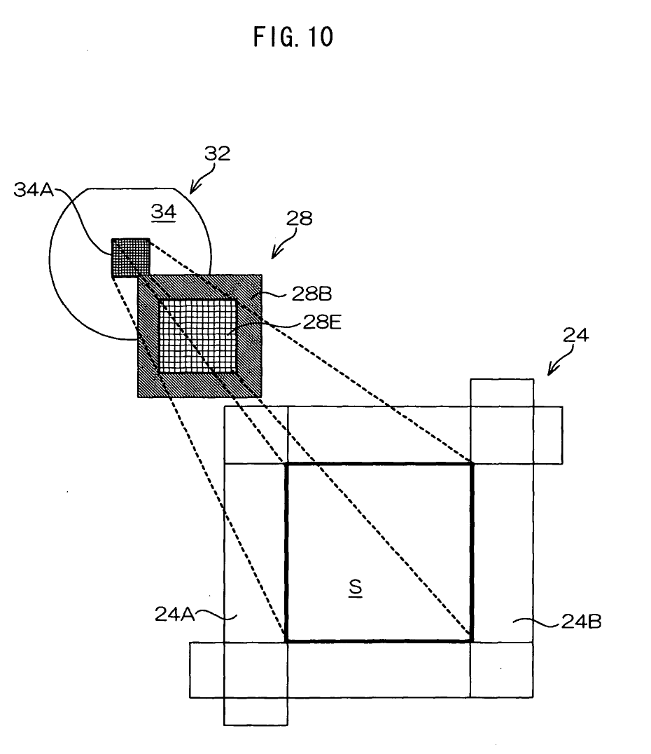

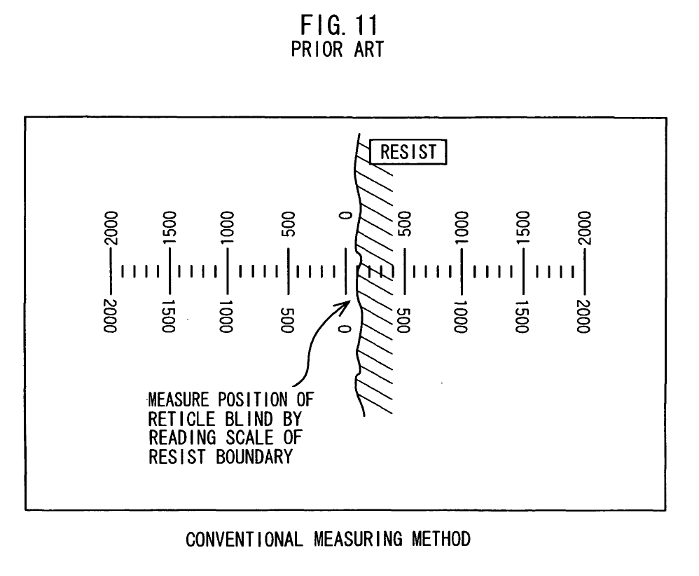

The above exemplary embodiment describes an example (see FIG. 3B) that uses a “photomask for measurement” in which numerous unit measurement patterns are formed over the entire mask. However, a “photomask for measurement” at which unit measurement patterns are formed at a portion of the mask may be used. For example, the reticle blind is structured from two, L-shaped light shielding plates, and one of the light shielding plates may be disposed fixedly and the other one light shielding plate can be moved. If at least the position of the boundary line in the x direction and the position of the boundary line in the y direction can be specified for one light shielding plate, the exposure region can be specified. In this case, the photomask for measurement shown in FIG. 9 can be used.

FIG. 9 is a plan view showing another structural example of a photomask for measurement. As shown in FIG. 9, at a photomask for measurement 28M′, the plural unit measurement patterns 52 are formed at one corner of the mask. The unit measurement patterns 52 are formed within the exposable region 28A (the portion surrounded by the one-dot chain line) of the photomask for measurement 28M′.

In this example, two pattern rows, in each of which four of the unit measurement patterns 52 are arrayed at predetermined intervals in the left-right direction, are lined-up at a predetermined interval in the top-bottom direction. Therebeneath, two pattern rows, in each of which two of the unit measurement patterns 52 are arrayed at a predetermined interval in the left-right direction, are lined-up at a predetermined interval in the top-bottom direction. As a result, twelve of the unit measurement patterns 52 are arrayed in the form of a 4×4 matrix whose lower-left four unit measurement patterns 52 are missing, and are disposed in an L-shape at the upper-right corner of the mask. The “arranged number” and “arrangement pitch” of the unit measurement patterns can be selected arbitrarily.

### <Summary of Method of Fabricating Semiconductor Device>

A semiconductor device such as an IC, an LSI or the like is fabricated by successively carrying out: a designing process of designing the circuit pattern of the IC, LSI; a wafer preparing process of forming an oxide film, a nitride film on a wafer formed of silicon or the like; a circuit forming process of repeatedly carrying out photolithography by using a photomask on which a circuit pattern is delineated, so as to form elements and lines on the wafer; and an assembly process of dividing the wafer on which circuits are formed into chips, and packaging them.

In the photolithographic process that is carried out in the aforementioned circuit forming process, the boundary line on the photomask between the exposure region and the light shielded region that is shielded from light by the reticle blind can be detected objectively by the above-described “method of detecting an exposure boundary position”. The circuit pattern of the semiconductor device is formed within the exposure region of the photomask that exists at the inner side of the detected boundary line, and circuits are formed on the wafer by photolithography using this photomask.

Due thereto, a semiconductor device can be fabricated efficiently, without the need to provide a wide light shielding zone at the photomask, and while avoiding the problems of the effective surface area of the photomask being reduced and the number of products fabricated per wafer decreasing.

What is claimed is:

1. A method of detecting an exposure boundary position that detects a position of a boundary line between a light shielded region and an exposure region on a photomask due to a reticle blind in a semiconductor exposing device that has the reticle blind adjusting an opening surface area through which a light beam from a light source passes, and a holding member holding the photomask, and that irradiates a light beam, that passes through an opening of the reticle blind, onto the photomask that is held at the holding member, and projects and exposes a pattern formed on the photomask onto a photoresist on a wafer, the method comprising:
a) preparing a photomask for measurement at which is formed a pattern for measurement that includes a plurality of pattern rows in each of which a plurality of unit measurement patterns, at which a dimension of a projected image projected onto a photoresist changes linearly in accordance with a decrease in an exposure amount, are arrayed in a predetermined direction;
b) holding the photomask for measurement by the holding member;
c) adjusting the opening surface area of the reticle blind;
d) illuminating the light beam, that passes through the opening of the reticle blind, onto the photomask for measurement that is held by the holding member, and printing, on a photoresist, the measurement pattern that is formed at the photomask for measurement;
e) selecting, from the measurement pattern printed on the photoresist, at least one measurement region at which a plurality of projected images of unit measurement patterns are arrayed in a given direction so as to exist at both sides of the boundary line;
f) successively measuring, at the selected measurement region and from a measurement start position that is at an exposure region side toward a light shielded region side, dimensions of the projected images of the unit measurement patterns that are arrayed in the given direction; and
g) on the basis of a position at which an amount of change of the dimension of the projected image exceeds a predetermined threshold value, detecting a position of a boundary line between a light shielded region and an exposure region on the photomask in the given direction.

2. The method of detecting an exposure boundary position of claim 1, wherein the unit measurement pattern is structured so as to include at least a rectilinear grating pattern in which straight line portions of predetermined widths are arrayed in parallel at predetermined intervals in a direction orthogonal to the given direction.

3. The method of detecting an exposure boundary position of claim 1, wherein the selected measurement region includes three or more unit measurement patterns at which dimensions of projected images can be measured.

4. The method of detecting an exposure boundary position of claim 1, wherein, at the photomask for measurement, a plurality of pattern rows, at each of which a plurality of the unit measurement patterns are arrayed at predetermined intervals in the given direction, are lined-up at predetermined intervals in a direction orthogonal to the given direction, and a plurality of the unit measurement patterns are arrayed in a matrix form over an entire mask surface.

5. The method of detecting an exposure boundary position of claim 1, wherein the dimension of the projected image of the unit measurement pattern is measured by an optical-type dimension measuring device.

6. A method of fabricating a semiconductor device that fabricates a semiconductor device, the method comprising:
detecting a position of a boundary line between a light shielded region and an exposure region on a photomask in a semiconductor exposing device by using the method of detecting an exposure boundary position of claim 1;
forming a circuit pattern of a semiconductor device within an exposure region of the photomask that exists at an inner side of a detected boundary line;
holding, by the holding member, the photomask on which the circuit pattern is formed; and
illuminating a light beam, that passes through the opening of the reticle blind, onto the photomask held by the holding member, and printing the circuit pattern, that is formed on the photomask, onto a photoresist on a wafer.
